(19) United States
(12) Patent Application Publication
(10) Pub. No.: US 2017/0352833 A1
(43) Pub. Date: Dec. 7, 2017

(54) PACKAGE STRUCTURE OF FLEXIBLE OLED DEVICE AND DISPLAY DEVICE

(71) Applicant: Wuhan China Star Optoelectronics Technology Co., Ltd., Development Zone, Wuhan (CN)

(72) Inventor: Yun YU, Wuhan (CN)

(21) Appl. No.: 15/310,101

(22) PCT Filed: Jul. 1, 2016
(86) PCT No.: PCT/CN2016/088146

§ 371 Date: Nov. 10, 2016

(30) Foreign Application Priority Data
Jun. 7, 2016 (CN) 201610403720.1

(51) Int. Cl. H01L 51/52; H01L 51/00; H01L 27/32

(52) U.S. Cl. CPC H01L 51/5253; H01L 51/0097; H01L 27/3244; H01L 2251/5338

(57) ABSTRACT

The present invention provides a package structure of a flexible OLED device comprising a flexible display unit comprising a flexible substrate for supporting an OLED device and the OLED device positioned on the flexible substrate; a package film layer positioned on the flexible display unit, the package film layer comprising an organic package film layer and an inorganic package film layer; and an ultra-thin glass disposed on the package film layer and having a high property of blocking water and oxygen. The ultra-thin glass is bonded to the package film layer via a bonding adhesive.

### BACKGROUND OF THE INVENTION

### Field of Invention

The present invention relates to a field of OLED display technology, and more particularly to a package structure of a flexible OLED device and a display device.

### Description of Prior Art

Organic light emitting diode (OLED) devices have significant advantages of self-luminescence, fast response speed, low driving voltage, high contrast ratio, wide color gamut, high luminous efficiency, and so on, and thus they are widely utilized in fields of screens of mobile phones or displays of computers. In particularly, the flexible OLED display devices are bendable and easy to carry, so they become a main direction of search and development in a field of display technology.

Currently, a problem which restricts the development of the OLED devices is that lifespans of the OLED devices are shorter. A main reason is that an electrode layer and a light emitting layer which compose an OLED device are quite sensitive to water vapor and oxygen in the atmosphere. Performance of the device is decreased after water and oxygen erosion. Packaging is a key manufacturing process of the OLED device. With rising of the OLED devices, a specific package of the flexible OLED devices is proposed. In one aspect, it is required that a permeability of the package to water vapor is lower than 5×10-6 g/m2d and a permeability to oxygen is lower than 10-5 cm2/m2d. In another aspect, it is further required that the package structure has a bendable characteristic. As such, a conventional rigid package structure cannot meet the requirement, but a new package material and a package structure represented by a thin film package structure are revealed.

Although organic polymer films have good flexibility, ability of blocking penetration of water and oxygen is quite limited. Dense and pinhole-free inorganic films have higher ability of blocking water and oxygen, but it is difficult to manufacture films with high dense quality when they reach a predetermined thickness. The inorganic films have performance of a rigid structure and are easily broken. Currently, most international flexible package researches are based on a package structure with an alternate organic/inorganic multilayer film composite structure. As shown in FIG. 1, a numeral 10 is a flexible display unit. Organic thin films 101 and inorganic thin films 102 are alternately deposited on 10 in sequence for multiple cycles to achieve package effect. An advantage of combining the two types of films is that a thin film package layer with a strong ability of blocking water and oxygen and a bendable characteristic can be manufactured. However, a structure of the alternate organic/inorganic thin film package is complicated. When the cycles of depositing the thin films alternately are small, a high property of blocking water and oxygen cannot be achieved and lifespan of a device is affected. When the cycles of depositing the thin films alternately are large, a number of the deposited films is large. Accordingly, a manufacture process is complicated, and a product yield is easily decreased.

### SUMMARY OF THE INVENTION

An objective of the present invention is to provide a package structure of a flexible OLED device and a display device having a good bendable characteristic and capable of effectively preventing water and oxygen from penetration, so that lifespan and a bending resistance property of the display device can be effectively increased and the manufacture process is simpler.

To solve the above-mentioned technical problem, the present invention provides a package structure of a flexible OLED device, comprising:

A flexible display unit comprising a flexible substrate for supporting an OLED device and the OLED device positioned on the flexible substrate;

A package film layer positioned on the flexible display unit, the package film layer comprising an organic package film layer and an inorganic package film layer; and

An ultra-thin glass disposed on the package film layer and having a high property of blocking water and oxygen,

Where the ultra-thin glass is bonded to the package film layer via a bonding adhesive; the ultra-thin glass is an optically transparent adhesive; a thickness of the ultra-thin glass is 20 μm-100 μm.

The organic package film layer is disposed on the inorganic package film layer.

The organic package film layer is disposed under the inorganic package film layer.

A thickness of the organic package film layer is 300 nm-1000 nm.

A thickness of the inorganic package film layer is 50 nm-200 nm.

The organic package film layer is manufactured of an organic material comprising SiOxCyHz, SiNxCyHz, or SiOxNyCzHm.

The inorganic package film layer is manufactured of an inorganic material comprising silicon oxide, silicon nitride, silicon oxynitride, aluminum oxide, or zirconium dioxide.

The present invention further provides a package structure of a flexible OLED device, comprising:

A flexible display unit comprising a flexible substrate for supporting an OLED device and the OLED device positioned on the flexible substrate;

A package film layer positioned on the flexible display unit, the package film layer comprising an organic package film layer and an inorganic package film layer; and

An ultra-thin glass disposed on the package film layer and having a high property of blocking water and oxygen,

Where the ultra-thin glass is bonded to the package film layer via a bonding adhesive.

The organic package film layer is disposed on the inorganic package film layer.

The organic package film layer is disposed under the inorganic package film layer.

A thickness of the organic package film layer is 300 nm-1000 nm.

A thickness of the inorganic package film layer is 50 nm-200 nm.

The ultra-thin glass is an optically transparent adhesive.

A thickness of the ultra-thin glass is 20 μm-100 μm.

The organic package film layer is manufactured of an organic material comprising SiOxCyHz, SiNxCyHz, or SiOxNyCzHm.

The inorganic package film layer is manufactured of an inorganic material comprising silicon oxide, silicon nitride, silicon oxynitride, aluminum oxide, or zirconium dioxide.

According to the above-mentioned objective of the present invention, a display device is further provided and comprises a package structure of a flexible OLED device, comprising:

A flexible display unit comprising a flexible substrate for supporting an OLED device and the OLED device positioned on the flexible substrate;

A package film layer positioned on the flexible display unit, the package film layer comprising an organic package film layer and an inorganic package film layer; and

An ultra-thin glass disposed on the package film layer and having a high property of blocking water and oxygen,

Where the ultra-thin glass is bonded to the package film layer via a bonding adhesive.

The organic package film layer is disposed on the inorganic package film layer.

The organic package film layer is disposed under the inorganic package film layer.

A thickness of the ultra-thin glass is 20 μm-100 μm.

The package structures of the flexible OLED devices and the display devices provided by the present invention are different from the prior art in which the organic package thin films and inorganic package thin film are alternately deposited for multiple cycles. The disclosed package structures of the flexible OLED devices and the display devices have a higher property of blocking water and hydrogen and flexibility, so that the lifespan and a bending resistance property of the display devices can be effectively increased and the manufacture process is simpler.

### BRIEF DESCRIPTION OF THE DRAWINGS

To describe the technical solutions of the embodiments of the present invention more clearly, the following briefly introduces the accompanying drawings required for describing the embodiments. Apparently, the accompanying drawings in the following description show only some embodiments of the present invention, and those skilled in the art may still derive other drawings from these accompanying drawings without creative efforts.

FIG. 1 is a package structure of a flexible OLED device in the prior art;

FIG. 2 is a package structure of a flexible OLED device in accordance with a first embodiment of the present invention;

FIG. 3 is a package structure of a flexible OLED device in accordance with a second embodiment of the present invention; and

FIG. 4 is an OLED device in accordance with the present invention.

### DETAILED DESCRIPTION OF THE PREFERRED EMBODIMENTS

The following embodiments are referring to the accompanying drawings for exemplifying specific implementable embodiments of the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

A clear and complete description of technical solutions provided in the embodiments of the present invention will be given below, in conjunction with the accompanying drawings in the embodiments of the present disclosure. Apparently, the embodiments described below are merely a part, but not all, of the embodiments of the present disclosure. All of other embodiments, obtained by those skilled in the art based on the embodiments of the present disclosure without any inventive efforts, fall into the protection scope of the present disclosure.

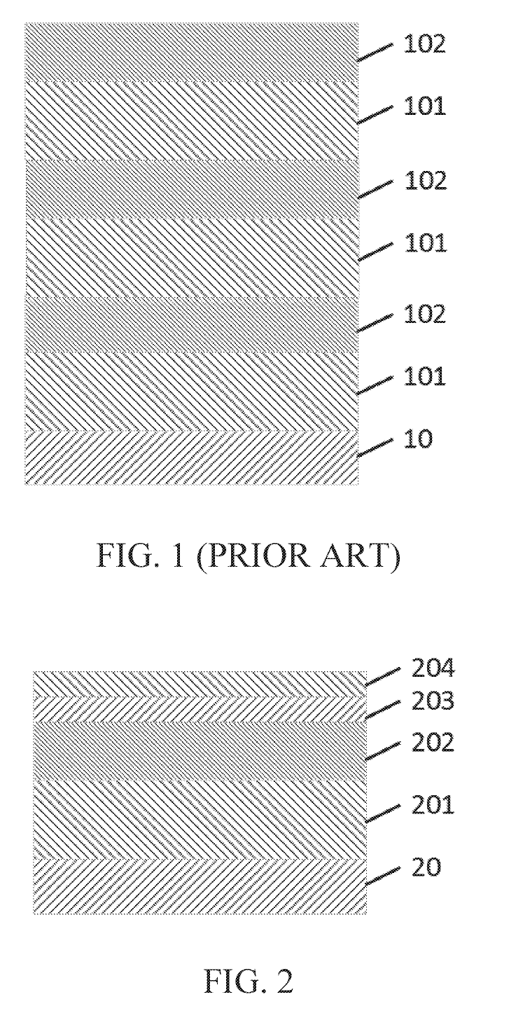

Please refer to FIG. 2, which is a package structure of a flexible OLED device in accordance with a first embodiment of the present invention.

The package structure of the flexible OLED device in accordance with the present embodiment of the present invention comprises a flexible display unit 20, which comprises a flexible substrate for supporting an OLED device and the OLED device positioned on the flexible substrate; a package film layer positioned on the flexible display unit 20, the package film layer comprising an organic package film layer 201 and an inorganic package film layer 202; and an ultra-thin glass 204 disposed on the package film layer and having a high property of blocking water and oxygen, where the ultra-thin glass 204 is bonded to the package film layer via a bonding adhesive 203.

The flexible display unit 20 is provided and comprises the flexible substrate for supporting an OLED device and the OLED positioned on the flexible substrate.

The flexible substrate is a polymer material and has main advantages of good flexibility, light weight, and impact resistance. A preferred polymer material of the present embodiment is polyimide (PI) or polyethylene terephthalate (PET).

As shown in FIG. 4, the OLED device comprises a first electrode 401, a second electrode 402, and an organic layer 403 positioned between the first electrode 401 and the second electrode 402. The organic layer 403 is an electroluminescent material. When the first electrode 401 and the second electrode 402 are energized, the luminescent material emits light.

When the package structure of the flexible OLED device in accordance with the present preferred embodiment is manufactured, the organic package film layer 201 is manufactured on the flexible display unit 20 firstly. Generally, the organic package film layer 201 is manufactured of an organic material, such as SiOxCyHz (an organic compound of carbon, hydrogen, and oxygen containing silicon), SiNxCyHz (an organic compound carbon, nitrogen, and hydrogen containing silicon), or SiOxNyCzHm (an organic compound carbon, nitrogen, oxygen, and hydrogen containing silicon). The organic package film layer 201 which is manufactured of the organic material has a good step coverage, so that an interface between the organic package film layer 201 and the flexible display unit 20 is bonded well. Preferably, a thickness of the organic package film layer 201 is 300 nm-1000 nm.

In the present embodiment, the organic package film layer 201 is manufactured by a plasma enhanced chemical vapor deposition (PECVD) method. In the plasma enhanced chemical vapor deposition method, working materials are excited to a plasma state via energy excitation, thereby producing reactions to form a thin film. In the method, a required basic reaction temperature is low, film quality is good, a number of pinholes is small, and cracks do not occur easily.

Then, the inorganic package film layer 202 is manufactured on the organic package film layer 201. Generally, the inorganic package film layer 202 is manufactured of an inorganic material, such as silicon oxide, silicon nitride, silicon oxynitride, aluminum oxide, or zirconium dioxide. The inorganic package film layer 202 which is manufactured of the inorganic material has a high property of blocking water and oxygen and is capable of preventing a part of water and oxygen in the atmosphere from entering the electrode layers and the light emitting layer, thereby avoiding that lifespan of the flexible OLED device is decreased because the electrode layers and the light emitting layer are eroded by water and oxygen. Preferably, a thickness of the inorganic package film layer 202 is 50 nm-200 nm.

When the inorganic package film layer 202 is manufactured of an inorganic material, such as silicon oxide, silicon nitride, or silicon oxynitride, the inorganic package film layer 202 is manufactured by a plasma chemical vapor deposition method.

When the inorganic package film layer 202 is manufactured of an inorganic material, such as aluminum oxide or zirconium dioxide, the inorganic package film layer 202 is manufactured by an atomic layer deposition (ALD) method. The atomic layer deposition method is a method capable of depositing material in a single atomic film on a surface of a substrate layer by layer. In depositing atomic layers, a chemical reaction of a new atomic film layer is related to a previous layer. In this method, only one layer of atoms is deposited each reaction. Since the deposition every cycle is self-limiting, a thickness of the film can be simply and accurately controlled by controlling a number of reaction cycles.

Finally, the ultra-thin glass 204 is adhered to the inorganic package film layer 202 via the bonding adhesive 203. The bonding adhesive 203 is an optically transparent adhesive. The package film layer is bonded to the ultra-thin glass 204 via the optically transparent adhesive. A bonding interface is highly dense, and thus effect of blocking water and oxygen is high. Furthermore, the light emitting layer of the OLED device is highly sensitive to a temperature, and it is unstable when the temperature is high than 80 degrees. Heating is not required in the bonding process, and thus display effect of the flexible OLED device is not affected.

Although the inorganic package film layer 202 has a higher property of preventing water and oxygen from penetration, a film surface per se is rough and small holes exist. External water and oxygen easily penetrate via the small holes, thereby decreasing a property of blocking water and oxygen of the thin film package structure. Accordingly, the ultra-thin glass 204 with the property of highly blocking water and oxygen is adhered to the package film layer via the optically transparent adhesive.

A thickness of the ultra-thin glass 204 is 20 μm-100 μm, and a preferred value is 50 μm in the present embodiment. The ultra-thin glass 204 has similar performance to that of a glass which is utilized in a general panel industry, but the thickness is ultra-thin and the property of blocking water and hydrogen is significantly higher than that of the package film layer.

The package structure of the flexible OLED device in accordance with the present embodiment of the present invention has a higher property of blocking water and hydrogen and flexibility, so that the lifespan and a bending resistance property of the display device can be effectively increased and the manufacture process is simpler.

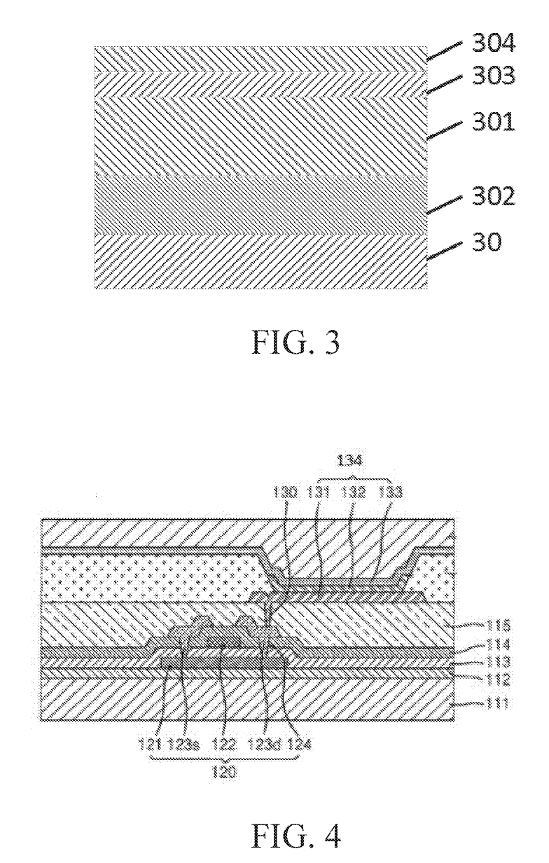

Please refer to FIG. 3, which is a package structure of a flexible OLED device in accordance with a second embodiment of the present invention.

A difference between the package structure of the flexible OLED device in accordance with the second embodiment of the present invention and the first embodiment is that the organic package film layer is positioned on the inorganic package film layer. By covering the flexible display unit with the inorganic package film layer firstly, most of water and oxygen can be blocked. Then, the inorganic package film layer is covered by the organic package film layer to increase the flexibility. Finally, the ultra-thin glass is adhered to the organic package film layer via the bonding adhesive, so that the flexible OLED device has a high property of blocking water and hydrogen and flexibility.

The package structure of the flexible OLED device in accordance with the present embodiment of the present invention comprises a flexible display unit 30, which comprises a flexible substrate for supporting an OLED device and the OLED device positioned on the flexible substrate; a package film layer positioned on the flexible display unit 30, the package film layer comprising an organic package film layer 301 and an inorganic package film layer 302; and an ultra-thin glass 304 disposed on the package film layer and having a high property of blocking water and oxygen, where the ultra-thin glass 304 is bonded to the package film layer via a bonding adhesive 303.

The flexible display unit 30 is provided and comprises the flexible substrate for supporting an OLED device and the OLED positioned on the flexible substrate.

The flexible substrate is a polymer material and has main advantages of good flexibility, light weight, and impact resistance. A preferred polymer material of the present embodiment is polyimide (PI) or polyethylene terephthalate (PET).

As shown in FIG. 4, the OLED device comprises a flexible substrate 111, a buffer layer 112 positioned on the flexible substrate 111, a low temperature polycrystalline silicon thin film transistors 120 positioned on the buffer layer, and an OLED layer 134 positioned on the low temperature polycrystalline silicon thin film transistors 120. Specifically, the low temperature polycrystalline silicon thin film transistors 120 comprises an active layer 121 disposed on the buffer layer, an insulating layer 113 disposed on the active layer, a gate 122 disposed on the insulating layer 113, and a source 123s and a drain 123d disposed on the gate 122. An insulating layer 114 is disposed between the gate 122 and the source 123s and the drain 123d. The source 123s and the drain 123d contact the active layer via a contact hole 124.

A flat layer 115 is disposed between the OLED layer 134 and the low temperature polycrystalline silicon thin film transistors 120. The OLED layer 134 contacts the drain 123d of the low temperature polycrystalline silicon thin film transistors 120 via a contact hole 130. Specifically, the OLED layer 134 comprises a first electrode 131, a second electrode 133, and an organic layer 132 positioned between the first electrode 131 and the second electrode 133. The organic layer 132 is an electroluminescent material. When the first electrode 131 and the second electrode 133 are energized, the luminescent material emits light.

When the package structure of the flexible OLED device in accordance with the present preferred embodiment is manufactured, the inorganic package film layer 302 is manufactured on the flexible display unit 30 firstly. Generally, the inorganic package film layer 302 is manufactured of an inorganic material, such as silicon oxide, silicon nitride, silicon oxynitride, aluminum oxide, or zirconium dioxide. The inorganic package film layer 302 which is manufactured of the inorganic material has a high property of blocking water and oxygen and is capable of preventing a part of water and oxygen in the atmosphere from entering the electrode layers and the light emitting layer, thereby avoiding that lifespan of the flexible OLED device is decreased because the electrode layers and the light emitting layer are eroded by water and oxygen. Preferably, a thickness of the inorganic package film layer 302 is 50 nm-200 nm.

When the inorganic package film layer 302 is manufactured of an inorganic material, such as silicon oxide, silicon nitride, or silicon oxynitride, the inorganic package film layer 302 is manufactured by a plasma chemical vapor deposition method.

When the inorganic package film layer 302 is manufactured of an inorganic material, such as aluminum oxide or zirconium dioxide, the inorganic package film layer 302 is manufactured by an atomic layer deposition (ALD) method. The atomic layer deposition method is a method capable of depositing material in a single atomic film on a surface of a substrate layer by layer. In depositing atomic layers, a chemical reaction of a new atomic film layer is related to a previous layer. In this method, only one layer of atoms is deposited each reaction. Since the deposition every cycle is self-limiting, a thickness of the film can be simply and accurately controlled by controlling a number of reaction cycles.

Then, the organic package film layer 301 is manufactured on the inorganic package film layer 302. Generally, the organic package film layer 301 is manufactured of an organic material, such as SiOxCyHz, SiNxCyHz, or SiOxNyCzHm. Preferably, a thickness of the organic package film layer 201 is 300 nm-1000 nm.

In the present embodiment, the organic package film layer 301 is manufactured by a plasma enhanced chemical vapor deposition (PECVD) method. In the plasma enhanced chemical vapor deposition method, working materials are excited to a plasma state via energy excitation, thereby producing reactions to form a thin film. In the method, a required basic reaction temperature is low, film quality is good, a number of pinholes is small, and cracks do not occur easily.

Finally, the ultra-thin glass 304 is adhered to the organic package film layer 301 via the bonding adhesive 303. The bonding adhesive 303 is an optically transparent adhesive. The package film layer is bonded to the ultra-thin glass 304 via the optically transparent adhesive. A bonding interface is highly dense, and thus effect of blocking water and oxygen is high. Furthermore, the light emitting layer of the OLED device is highly sensitive to a temperature, and it is unstable when the temperature is high than 80 degrees. Heating is not required in the bonding process, and thus display effect of the flexible OLED device is not affected.

Although the inorganic package film layer 302 has a higher property of preventing water and oxygen from penetration, a film surface per se is rough and small holes exist. External water and oxygen easily penetrate via the small holes, thereby decreasing a property of blocking water and oxygen of the thin film package structure. Accordingly, the ultra-thin glass 304 with the property of highly blocking water and oxygen is adhered to the package film layer via the optically transparent adhesive.

A thickness of the ultra-thin glass 304 is 20 μm-100 μm, and a preferred value is 50 μm in the present embodiment. The ultra-thin glass 304 has similar performance to that of a glass which is utilized in a general panel industry, but the thickness is ultra-thin and the property of blocking water and hydrogen is significantly higher than that of the package film layer.

Based on the first preferred embodiment, the present preferred embodiment in which the organic package film layer is disposed on the inorganic package film layer also has a higher property of blocking water and hydrogen and flexibility, so that the lifespan and a bending resistance property of the display device can be effectively increased and the manufacture process is simpler.

A display device is further provided in accordance with an embodiment of the present invention which comprises the above-mentioned package structure of the flexible OLED device.

The package structure of the flexible OLED device is the same as the above-mentioned embodiments and not described repeatedly herein. Furthermore, structures of other parts of the display device can be referred to the prior art, and they are not described in detail herein. The display device may be a product or a component having a display function, such as an electronic paper, a television, a display, a digital photo frame, a mobile phone, or a tablet PC.

The package structures of the flexible OLED devices and the display devices provided by the embodiments of the present invention are different from the prior art in which the organic package thin films and inorganic package thin film are alternately deposited for multiple cycles. The disclosed package structures of the flexible OLED devices and the display devices have a higher property of blocking water and hydrogen and flexibility, so that the lifespan and a bending resistance property of the display devices can be effectively increased and the manufacture process is simpler.

The package structures of the flexible OLED devices and the display devices in accordance with the embodiments of the present invention are described in detail above. As is understood by a person skilled in the art, the foregoing preferred embodiments of the present invention are illustrative rather than limiting of the present invention. It is intended that they cover various modifications and similar arrangements be included within the spirit and scope of the present invention, the scope of which should be accorded the broadest interpretation so as to encompass all such modifications and similar structures.

What is claimed is:

1. A package structure of a flexible OLED device, comprising:
a flexible display unit comprising a flexible substrate for supporting an OLED device and the OLED device positioned on the flexible substrate;
a package film layer positioned on the flexible display unit, the package film layer comprising an organic package film layer and an inorganic package film layer; and
an ultra-thin glass disposed on the package film layer and having a high property of blocking water and oxygen,
wherein the ultra-thin glass is bonded to the package film layer via a bonding adhesive; the ultra-thin glass is an optically transparent adhesive; a thickness of the ultra-thin glass is 20 μm-100 μm.

2. The package structure of the flexible OLED device of claim 1, wherein the organic package film layer is disposed on the inorganic package film layer.

3. The package structure of the flexible OLED device of claim 1, wherein the organic package film layer is disposed under the inorganic package film layer.

4. The package structure of the flexible OLED device of claim 1, wherein a thickness of the organic package film layer is 300 nm-1000 nm.

5. The package structure of the flexible OLED device of claim 1, wherein a thickness of the inorganic package film layer is 50 nm-200 nm.

6. The package structure of the flexible OLED device of claim 1, wherein the organic package film layer is manufactured of an organic material comprising SiOxCyHz, SiNxCyHz, or SiOxNyCzHm.

7. The package structure of the flexible OLED device of claim 1, wherein the inorganic package film layer is manufactured of an inorganic material comprising silicon oxide, silicon nitride, silicon oxynitride, aluminum oxide, or zirconium dioxide.

8. A package structure of a flexible OLED device, comprising:
a flexible display unit comprising a flexible substrate for supporting an OLED device and the OLED device positioned on the flexible substrate;
a package film layer positioned on the flexible display unit, the package film layer comprising an organic package film layer and an inorganic package film layer; and
an ultra-thin glass disposed on the package film layer and having a high property of blocking water and oxygen,
wherein the ultra-thin glass is bonded to the package film layer via a bonding adhesive.

9. The package structure of the flexible OLED device of claim 8, wherein the organic package film layer is disposed on the inorganic package film layer.

10. The package structure of the flexible OLED device of claim 8, wherein the organic package film layer is disposed under the inorganic package film layer.

11. The package structure of the flexible OLED device of claim 8, wherein a thickness of the organic package film layer is 300 nm-1000 nm.

12. The package structure of the flexible OLED device of claim 8, wherein a thickness of the inorganic package film layer is 50 nm-200 nm.

13. The package structure of the flexible OLED device of claim 8, wherein the ultra-thin glass is an optically transparent adhesive.

14. The package structure of the flexible OLED device of claim 8, wherein a thickness of the ultra-thin glass is 20 μm-100 μm.

15. The package structure of the flexible OLED device of claim 8, wherein the organic package film layer is manufactured of an organic material comprising SiOxCyHz, SiNxCyHz, or SiOxNyCzHm.

16. The package structure of the flexible OLED device of claim 8, wherein the inorganic package film layer is manufactured of an inorganic material comprising silicon oxide, silicon nitride, silicon oxynitride, aluminum oxide, or zirconium dioxide.

17. A display device, comprising a package structure of a flexible OLED device, comprising:
a flexible display unit comprising a flexible substrate for supporting an OLED device and the OLED device positioned on the flexible substrate;
a package film layer positioned on the flexible display unit, the package film layer comprising an organic package film layer and an inorganic package film layer; and
an ultra-thin glass disposed on the package film layer and having a high property of blocking water and oxygen,
wherein the ultra-thin glass is bonded to the package film layer via a bonding adhesive.

18. The display device of claim 17, wherein the organic package film layer is disposed on the inorganic package film layer.

19. The display device of claim 17, wherein the organic package film layer is disposed under the inorganic package film layer.

20. The display device of claim 17, wherein a thickness of the ultra-thin glass is 20 μm-100 μm.
